(19) United States
(12) Patent Application Publication
(10) Pub. No.: US 2012/0017989 A1
(43) Pub. Date: Jan. 26, 2012

(54) Metal and metal oxide surface texturing

(76) Inventors: Pai-Chun Chang, Sunnyvale, CA (US); Chung-Jen Chien, Sunnyvale, CA (US); Pengfel Qi, Sunnyvale, CA (US)

(21) Appl. No.: 13/216,402

(22) Filed: Aug. 24, 2011

Related U.S. Application Data
(63) Continuation of application No. 12/699,107, filed on Feb. 3, 2010, now Pat. No. 8,045,919.
(60) Provisional application No. 61/376,317, filed on Aug. 24, 2010.

(51) Int. Cl. H01L 31/0232; C25D 5/34; C25D 5/48

(52) U.S. Cl. 136/259; 205/223; 205/206

(57) ABSTRACT

A method of texturing a metal provides a metal with a thickness of 50 to 400 μm. The metal is anodized, etched and then textured in a first texturing step to produce a first textured surface of the metal. A textured metal is produced with a dimpled surface of dimples with diameters of 5 nm to 2 and a depth of from 2 nm to 2 μm.

### CROSS-REFERENCE TO RELATED APPLICATIONS

This application claims the benefit of U.S. Application No. 61/376,317 filed Aug. 24, 2011, which application is fully incorporated herein by reference.

### BACKGROUND OF THE INVENTION

1. Field of the Invention

The present invention relates to devices and methods for texturing metallic films, foils or sheets and the like, and more particularly to textured metal metallic films, foils or sheets that are utilized in a variety of devices including but not limited to photovoltaic devices (PV) devices.

2. Description of the Related Art

Solar cells are photovoltaic devices that convert sunlight directly into electric power. PV or solar cells typically have one or more p-n junctions. Each junction comprises two different regions within a semiconductor material where one side is denoted as the p-type region and the other as the n-type region. When the p-n junction of the PV cell is exposed to sunlight (consisting of energy from photons), the sunlight is directly converted to electricity through the PV effect. PV solar cells generate a specific amount of electric power and cells are tiled into modules sized to deliver the desired amount of system power. PV modules are joined into panels with specific frames and connectors.

Thin film types of solar cells are commonly formed on a glass or metallic substrate. In practice, it is desired that incident light transmitted into the solar cell efficient convert as such as the optical energy to electrical energy as possible. However, since sunlight may be scattered, refracted, diffracted, or reflected during transmission, there is insufficient light flux for direct conversion to be cost effective.

Accordingly, several different techniques have been developed to enhance light trapping in the solar cells to improve conversion efficiency. For example, different coatings may be applied to the substrate surface to minimize surface reflectance, thereby allowing a higher percentage of incident light to enter in the solar cells, as opposed to being reflecting away from the solar cell. Alternatively, a surface texture may be provided to increase the surface roughness, thereby assisting the light to be scattered and absorbed in the solar cell. Conventional surface texturing process often utilizes alcohol related compounds as a chemical source for substrate surface treatment. However, alcohol related compounds are flammable, which are fire hazard and be in environmental safety concern, thereby requiring special safety measures during processing. Also, alcohols evaporate at the temperatures needed to assure that the chemical activity of the etchants in the texturing solution is in an optimum range to effectively perform the texturing process. Evaporation of the alcohol components from the texturing bath thus leads to an unstable texturing bath composition when the processes are run at these elevated temperatures.

Therefore, there is a need for an improved surface texture processes, and devices made with such improved processes, including but not limited to PV devices.

### SUMMARY OF THE INVENTION

Accordingly, an object of the present invention is to provide methods for creating a controllable texturing surface on metallic films, foils or sheets (hereafter collectively “metal”).

Another object of the present invention is to provide methods for creating controllable texturing surface on a metal.

Yet another object of the present invention is to provide methods for creating large surface areas to improve energy conversion and energy storage efficiency of devices.

Still another object of the present invention is to provide methods for creating controllable texturing surfaces on a metal using economical wet processing.

Another object of the present invention is to provide methods for creating controllable texturing surfaces on a metal for mass production by roll-to-roll manufacturing.

These and other objects of the present invention are achieved in, a method of texturing a metal. A metal is provided with a thickness of 50 to 400 μm. The metal is anodized, etched and then textured in a first texturing step to produce a first textured surface of the metal. A textured metal is produced with a dimpled surface of dimples with diameters of 5 nm to 2 μm, and a depth of from 2 nm to 2 μm.

In another embodiment of the present invention, a photovoltaic cell is provided that includes, a substrate, barrier layer, contact layer, absorber layer, window layer and a transparent conductive oxide (TCO). A textured metal layer is either a bottom substrate or electrode. The textured metal layer has a dimpled surface of dimples with diameters of 5 nm to 2 μm, and a depth of from 2 nm to 2 μm.

### BRIEF DESCRIPTION OF THE DRAWINGS

FIG. 1 is a flow chart illustrating one embodiment of a process to form a textured metal of the present invention.

FIG. 2 illustrates and embodiment of the present invention with textured metal that has a dimpled surface of dimples.

FIG. 3 is a schematic diagram illustrating an embodiment of the present invention to form a textured metal surface of the present invention.

FIG. 4 illustrates one embodiment of a process flow of a photovoltaic cell fabrication based on textured Al film of the present invention.

FIG. 5 illustrates an optical light diffuser made with a textured metal in one embodiment of the present invention.

FIG. 6 is a block diagram of the process for the FIG. 5 embodiment.

FIG. 7 illustrates a PV cell made with a textured metal in one embodiment of the present invention.

FIG. 8 illustrates a block diagram of the process used in the FIG. 7 embodiment.

FIG. 9 illustrates reflectance spectrum data of different textured surfaces in embodiments of the present invention.

### DETAILED DESCRIPTION OF THE PREFERRED EMBODIMENTS

In various embodiments, the present invention provides methods for texturing metals, including but not limited to, Al, Ti, W, Hf, Ta, Zr, Nb, other metals and the like. Such textured metals have a variety of different applications including but not limited to, optical devices such as a filters, diffusers, reflectors, PV's, waveguides and electrochemical electrodes for water splitting, biosensors, chemical sensors, batteries, energy storage and the like.

Texturing is basically an anodization process. After the pre-treatment and etching process, the surface will be rough. In one embodiment of the present invention a second anodization step is provided which is a texturing process obtain better controllability. The textured surface pattern looks like closed-packed dimples. The dimple diameter size can be controlled by the applied voltage, and in a range from 5 nm to 2 μm. The depth of the dimple is from 2 nm to 2 μm.

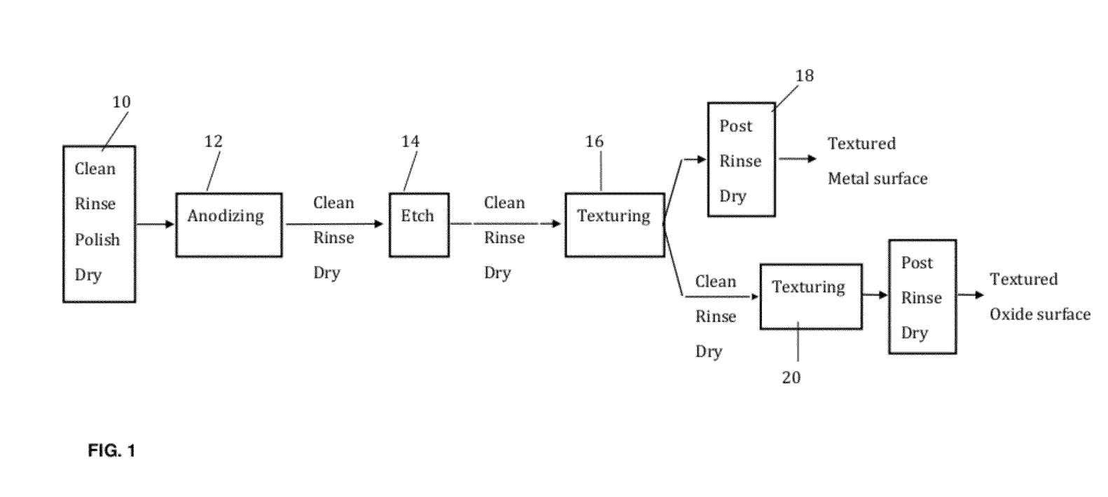

FIG. 1 is a flow chart that illustrates one embodiment of the methods of the present invention. With the present invention the metal cleaned/rinsed, polished/dried 10, anodized 12, etched 14, cleaned/rinsed/dried, first textured 16, and either followed by a post rinse and dry 18 to provide the textured metal oxide surface, or alternately, a second etching step 20 can be performed following by rinse/dry to provide textured metal surface.

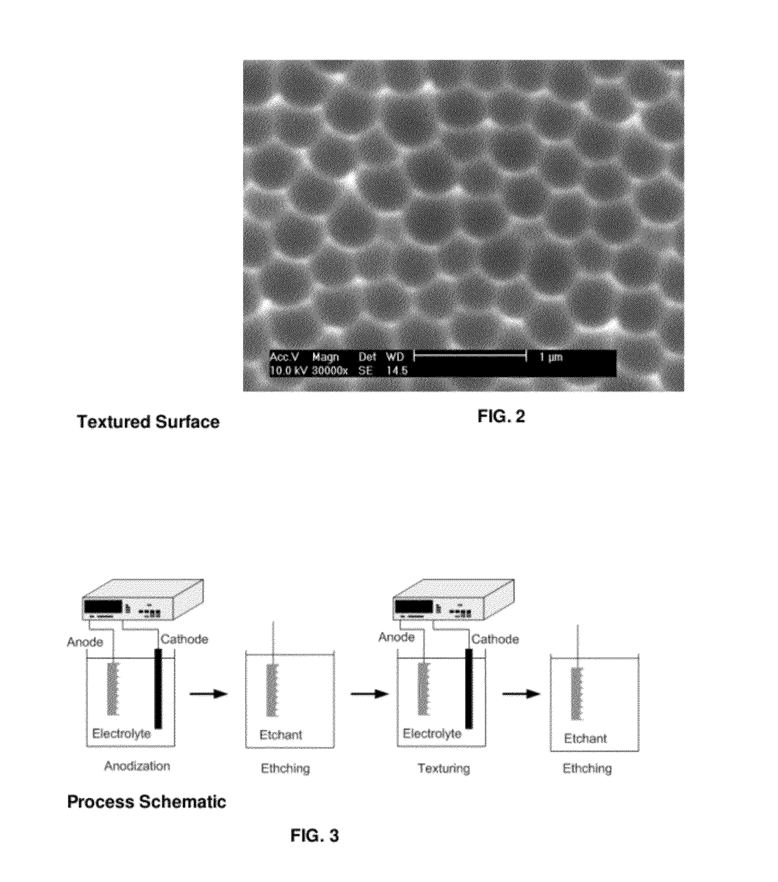

In one specific embodiment, a method of texturing the metal uses an initial metal that has a thickness of 50 to 400 μm. The metal is anodized, etched and textured in a first texturing step to produce a first textured surface of the metal oxide. With additional etching process to remove oxide layer, the textured pure metal surface is obtained. As illustrated in FIG. 2, a textured metal with a dimpled surface is produced. In one specific embodiment, the dimples have diameters of 5 nm to 2 and a depth of from 2 nm to 2 μm. The process schematic is illustrated in FIG. 3.

In one embodiment, the texturing is achieved with a metal. The metal can have a length of 1-2 m, a width 0.5-2 m and a thickness of 50-400 μm. The metal is first cleaned in DI water, solvent, or a mixture, and the like, to remove particles and organic soil. It is then polished by a series of standard mechanical and electrochemical process and rinsed by solvents and DI water. As a non-limiting example, the mechanical grinding and polishing can be up to grit 5000. The electro-polishing is to obtain a smooth surface of metal sheet. It has to be mirror finishing with a roughness of no more than 1 μm. Roughness is a measurement of height variation compared to a mean value. The smooth surface is important for thin film device fabrication to avoid non-uniform film and cracking.

The cleaned metal is then dried and transported to a wet chemical bath. The solution in the chemical bath contains organic/inorganic acids, such as hydrofluoric acid, hydrochloric acid, oxalic acid, phosphoric acid, sulfuric acid, tartaric acid, citric acid, acid mixtures, and the like. The solution also can include surfactants including but not limited to, ethylene glycol, poly-ethylene glycol, and the like, with/without pH buffer. The solution in the chemical bath is stirred and agitated. As a non-limiting example, this can be achieved with the use of a mechanically driven agitator or by a flow injector with a circulation pump.

The processing temperature of the chemical bath is set according to desired processing throughput and film quality. As a non-limiting example, the temperature range can be from −30° C. to 200° C., 0° C. to 175° C., 50° C. to 100° C., and the like. As a non-limiting example, the processing temperature is controlled by immersion heaters and cooling coils.

The metal is placed in the chemical bath with an electrical lead connection for applying electrical current. The contact of the lead to the metal is sealed from the solution. As non-limiting examples, the contact can be made of stainless steel, copper, titanium, nickel, alloys and the like.

The cathode is placed in the chemical bath and serves as the counter electrode. As non-limiting examples, the cathode can be made of lead, graphite, stainless steel, platinum, alloys and the like.

Suitable power supplies provide a DC or DC+AC voltage potential to anodize the metal. The DC voltage can be 0.1V to 600V. The AC voltage can be 0.1 V to 100V. The time of the anodization process can range from a few minuets to several hours. The metal is then rinsed sequentially with warm water, DI water, and/or solvents and then dried.

The oxide grown during the anodization process needs to be removed by the etching step. The etching is done in an acid bath containing but not limited to hydrofluoric acid, hydrochloric acid, chromic acid, nitric acid, phosphoric acid, sulfuric acid, and mixtures, and the like. The etching temperature can be 30° C. to 100° C. The etching time can be 20 to 120 minutes.

After rising, the metal is placed in the texturing solution bath. The solution in the chemical bath contains organic/inorganic acids, such as hydrofluoric acid, hydrochloric acid, oxalic acid, phosphoric acid, nitric acid, sulfuric acid, tartaric acid, citric acid, acid mixtures, and the like. The solution also contains surfactants, such as ethylene glycol, polyethylene glycol, and the like, with/without pH buffer. The solution in the chemical bath needs to be stirred and agitated by mechanically driven agitator or flow injector with circulation pump. The processing temperature is controlled by immersion heaters and cooling coils.

Texturing is a second anodization process. The metal is placed in the chemical bath with a lead connection same as in anodization step. Power supplies are used to provide DC or DC+AC voltage potential to anodize the metal. The DC voltage can be 0.1V to 600V. The AC voltage can be 0.1V to 100V. The time of the anodization process can range from few minuets to several hours.

During texturing which is the second anodization process, the electric field induced ion diffusion would form certain pattern. Metal oxide formed under high electric field strength has porous channel-like structure while the acidic solution etches into metal and form dimpled surface. The dimple size and texture roughness can be controlled by the applied electric field (voltage). After rinsing and cleaning, a textured metal oxide is obtained and observed on top of the metal substrate.

To obtain the textured metal surface, an additional (second) etching step is required. The etching is done in an acid bath containing but not limited to hydrofluoric acid, hydrochloric acid, chromic acid, nitric acid, phosphoric acid, sulfuric acid, and mixtures, and the like. The etching temperature can be 30° C. to 100° C. The etching time can be 20 to 120 minutes.

The textured metal can serve as the bottom substrate or electrode for a variety of devices including but not limited to, solar cells, battery electrodes and the like.

In one specific embodiment, the present invention provides improved surface textures, and processes, for thin-film PV solar cells. PV technologies, include but not limited to those based on a-Si, Tf-Si, CdTe, CIGS, DSG and the like. The thin film PV solar cells (TFSC) of the present invention are generally made depositing one or more thin layers thin film of photovoltaic material on a substrate. The thickness range of such a layer is wide and varies from a few nanometers to tens of micrometers.

In one embodiment, the thin film PV solar cell is a silicon thin-film cell that uses amorphous (a-Si or a-Si:H), protocrystalline, nanocrystalline (nc-Si or nc-Si:H) or black silicon. Thin-film silicon is opposed to wafer (or bulk) silicon (monocrystalline or polycrystalline). The silicon is mainly deposited by chemical vapor deposition, typically plasma-enhanced (PE-CVD), from silane gas and hydrogen gas. Other deposition techniques being investigated include sputtering and hot wire techniques. The silicon is deposited on glass, plastic or metal which has been coated with a layer of transparent conducting oxide (TCO).

A p-i-n structure is usually used, as opposed to an n-i-p structure. This is because the mobility of electrons in a-Si:H is roughly 1 or 2 orders of magnitude larger than that of holes, and thus the collection rate of electrons moving from the p- to n-type contact is better than holes moving from p- to n-type contact. Therefore, the p-type layer should be placed at the top where the light intensity is stronger, so that the majority of the charge carriers crossing the junction would be electrons.

In one embodiment the PV device is a CIS cell that includes a substrate, back contact layer, CIS layer, window layer and front contact layer. The substrate can be soda lime glass, stainless steel, polyimide or other film. As non-limiting examples, back contact can be a molybdenum (Mo) layer, front contact 18 can be a transparent conducting oxide (TCO), such as indium tin oxide (ITO) or doped zinc oxide (ZnO), window layer 16 can include one or more layers of cadmium-sulfide (CdS), zinc-sulfide (ZnS), zinc oxide (ZnO) and other large bandgap semiconductors.

Several methods of CIS can be used including but not limited to those described in U.S. Pat. No. 4,798,660, incorporated by reference herein, a 2-step deposition process consisting of (1) deposition of precursor layers and (2) chemical reaction of selenization resulting in a formation of a thin CIS layer. Other suitable CIS manufacturing methods include co-evaporation technique as described in U.S. Pat. No. 4,335,266, field-assisted simultaneous synthesis and transfer process as described in U.S. Pat. No. 6,559,372, co-sputtering method as described in U.S. Pat. No. 6,974,976, both incorporated by reference herein.

FIG. 4 illustrates one embodiment of a process flow of a photovoltaic cell fabrication based on textured Al film. In this embodiment, material A can be coated on top of Al with/without metal such as, Ti, Cu, Au, Ag, Cd, Ni or alloy, and the like film. Material A can be coated on top of Al with/without dielectric buffer such as, SiO₂, Si₃N₄, MoO₃, CuO, WO₃, TiO₂, TiN or mixture, and the like film. Material B can be coated on top of A. The interface between A and B is used for a photovoltaic energy conversion purpose. A transparent conductive oxide (ITO, ZnO) film is coated on top of Material B. A metal grid such as, Ag, Al, Ni, Mo, Cr alloy and the like, is metallization on the top surface as a charge carrier collector.

### EXAMPLE 1

### Optical Light Diffuser

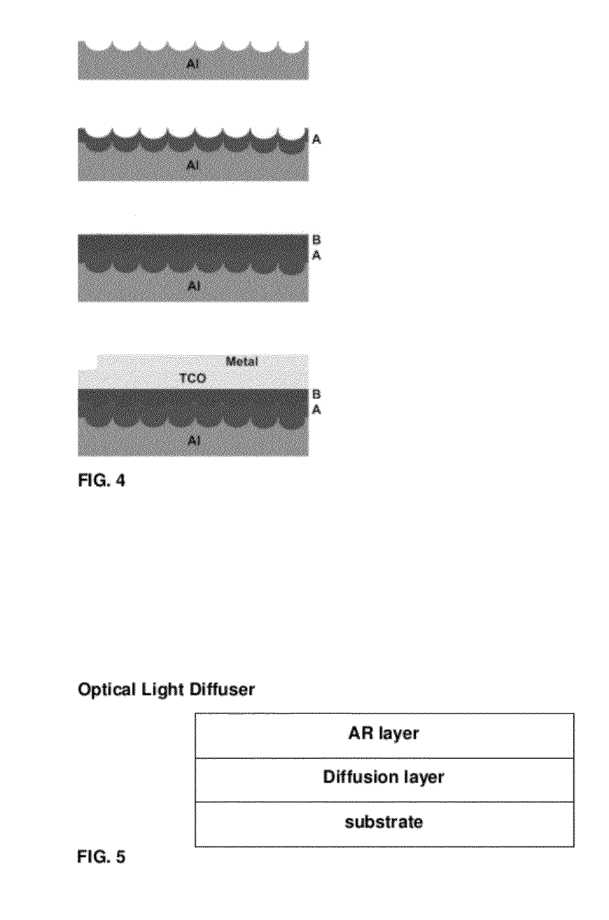

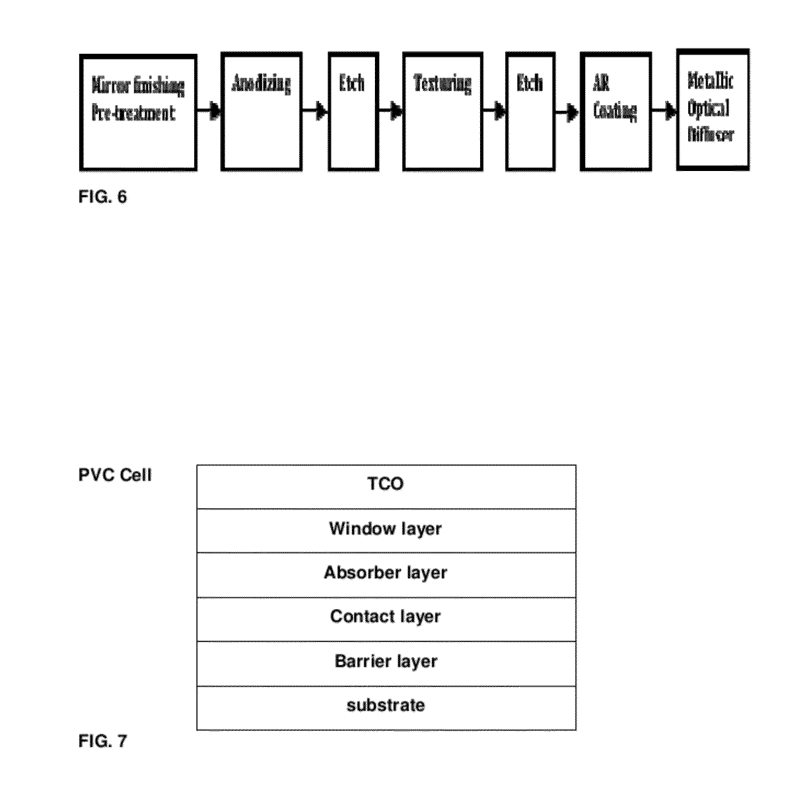

An optical light diffuser is made with the present invention. Referring to FIG. 5, the optical light diffuser 22 includes, a substrate 24, diffusive layer 26 and an AR coating 28. A metal is first cleaned in DI water, solvent, or mixture to remove particles and organic soil. It then be polished by a series of mechanical and electrochemical process and rinsed by solvents and DI water. The cleaned metal is then dried and transported to a wet chemical bath. Al is anodized in 0.1% phosphoric mixed with ethylene glycol and pH buffer. The solution in the chemical bath needs to be stirred and agitated by mechanically driven agitator or flow injector with circulation pump. The temperature is controlled by cooling coil connected to an external chiller. FIG. 6 is a block diagram illustrating the process of making the optical light diffuser.

Power supplies are used to provide DC or DC+AC voltage potential to anodize the metal. The voltage is set at 300V. The time of the anodization process is 1 hour. When finished, move to cleaning step. The metals rinsed sequentially with warm water, DI water, and/or solvents, and then dried. The grown oxide is removed by the acid etching bath containing 10% wt phosphoric acid and 3.6% wt chromic acid (20% w/V) for about 40 minutes. The temperature is controlled at 80° C. by immersion heating unit. The finished textured Al can be cut into desired size and used as optical light diffuser.

### EXAMPLE 2

### PV Cell

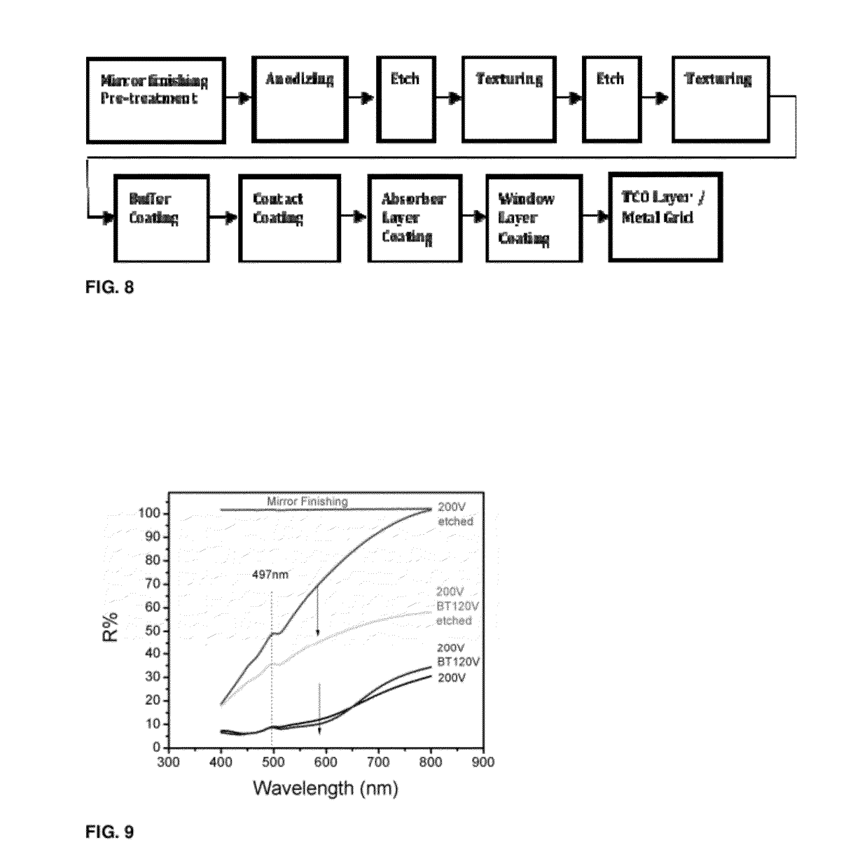

As illustrated in FIGS. 7 and 8, in one embodiment, a PV cell 30 is made using the textured metal of the present invention. The PV cell 30 includes, a substrate 32, barrier layer 34, contact layer 36, absorber layer 36 (p or n type), window layer 38 (n or p type) and a transparent conductive oxide (TCO) 40. The cell includes a textured Al layer 42 as the bottom substrate or electrode.

In one embodiment, pure Al (99.99%) is anodized in a 4% (w/V) citric acid that is mixed with 70% (w/V) ethylene glycol at 10° C. at 500 V for 1 hour.

The Al, including the anodic aluminum oxide, is immersed in the acidic solution at 50-100° C. to etch the anodic aluminum oxide layer. As a non-limiting example, the acid solution can be sulfuric acid, phosphoric acid, chromic acid, nitric acid, a mixture of above acids and the like. As a non-limiting example, the immersion etching can be at, 63° C. 6% wt phosphoric acid (80% wt) and 1.8% wt chromic acid (10% w/V) for 1 hour.

The finishing aluminum surface then contains a textured feature with a certain roughness. The roughness is controllable and can be in the range from 5 um down to 10 nm, 8 nm, 5, nm, 3, nm 2 nm 1 nm and the like. In a non-limiting example, the textured Al is used as the bottom substrate in a-Si:H solar cell. A diffusion barrier layer can be ZnO, ITO, and the like. is deposited on the textured Al. A buffer metal layer using Ni, Mo, Cr, Ag, and alloy is deposited on the barrier layer.

A single junction or multi-junction tandem structure of a Si/-Si can be deposited by PECVD process. TCO is deposited as the electron collector. Metal grid deposition or laser scribing technique can be used to define individual cell and connect to bus bar for current collection.

As a non-limiting example, several treated surfaces with different texturing parameters are created, compared and measured by reflection spectroscopy. FIG. 9 illustrates reflectance spectrum data of different treated surface. Mirror finishing shows a high reflectance of 99% while different textured surfaces show much lower reflectance.

1. A method of texturing a metal, comprising:
providing a metal that has a thickness of 50 to 400 μm.
anodizing the metal;
etching the metal;
texturing the metal in a texturing step to produce a metal oxide surface; and
etching the textured metal oxide surface to produce a textured surface of the metal, the textured surface having a dimpled surface of dimples with diameters of 5 nm to 2 μm, and a depth of from 2 nm to 2 μm

2. The method of claim 1, further comprising:
cleaning the metal; and
polishing the metal prior to anodizing the metal.

3. The method of claim 1, further comprising:
polishing the metal surface prior to anodizing to provide a metal surface with a average roughness no greater than 1 μm, wherein roughness is a measurement of height variation compared to a mean value.

4. The method of claim 1, wherein during anodization and oxide is grown on the metal that is removed by etching.

5. The method of claim 1, wherein the etching is done in an acid bath.

6. The method of claim 1, wherein the etching is done at a temperature of 30° C.-100° C.

7. The method of claim 6, wherein the etching is done from 20-120 minutes.

8. The method of claim 1, wherein the first texturing is done in a texturing solution bath.

9. The method of claim 8, wherein the solution bath includes acids and surfactants.

10. The method of claim 8, wherein the first texturing step is a second anodization process.

11. The method of claim 1, wherein during the first texturing step, an electric field is provided that induces ion diffusion to form a dimple pattern on the surface of the metal.

12. The method of claim 11, wherein the dimple surface of the textured metal has porous channel-like structures that form the dimpled surface.

13. The method of claim 1, wherein dimple size and texture roughness is controlled by an applied electric field.

14. The method of claim 1, wherein the dimpled surface is a textured metal oxide surface.

15. The method of claim 1, further comprising:
etching the metal oxide in a second etching step to produce a textured surface of the metal

16. The method of claim 1, wherein the metal has a thickness of from 50-400 μm.

17. The method of claim 1, wherein the metal has a width of 0.5-2 m.

18. The method of claim 1, wherein the metal has a length of 1-2 m applying a second texturing step.

19. The method of claim 1, further comprising:
mechanically grinding and polished the metal.

20. The method of claim 1, wherein the metal is selected from at least one of, Al, Ti, W, Hf, Ta, Zr and Nb.

21. The method of claim 1, wherein the metal is a foil or a sheet.

22. The method of claim 1, wherein the metal is a pure metal.

23. The method of claim 1, wherein the metal is a compound.

24. The method of claim 1, wherein the metal is a composition that includes non-metals.

25. The method of claim 1, wherein the textured metal is included in a device selected from at least one of, an optical device, reflectors, PV, waveguides electrochemical electrodes, biosensors, chemical sensor, battery and energy storage device.

26. The method of claim 1, wherein the textured metal serves as a bottom substrate or electrode for a variety of devices.

27. A photovoltaic cell, comprising:
a substrate;
a buffer layer;
a contact layer;
an absorber layer;
a window layer;
a transparent conductive oxide (TCO) and
a textured metal layer as a bottom substrate or electrode., wherein the textured metal layer has a dimpled surface of dimples with diameters of 5 nm to 2 μm, and a depth of from 2 nm to 2 μm.

28. The photovoltaic cell of claim 27, wherein the absorber layer is p or n type.

29. The photovoltaic cell of claim 27, wherein the window layer is p or n type.

30. The method of claim 27, wherein the dimple surface of the textured metal has porous channel-like structures that form the dimpled surface.

31. The method of claim 27, wherein dimple size and texture roughness is controlled by an applied electric field.

32. The method of claim 27, wherein the dimpled surface is a textured metal oxide surface.

33. The method of claim 27, wherein the metal has a thickness of from 50-400 μm.

34. The method of claim 27, wherein the metal has a width of 0.5-2 m.

35. The method of claim 27, wherein the metal has a length of 1-2 m

36. The method of claim 27, wherein the metal is selected from at least one of, Al, Ti, W, Hf, Ta, Zr and Nb.

37. The method of claim 27, wherein the metal is a foil or a sheet.

38. The method of claim 27, wherein the metal is a pure metal.

39. The method of claim 27, wherein the metal is a compound.

40. The method of claim 27, wherein the metal is a composition that includes non-metals.
